(19) United States
(12) Patent Application Publication
(10) Pub. No.: US 2002/0100963 A1
(43) Pub. Date: Aug. 1, 2002

(54) Semiconductor package and semiconductor device

(75) Inventors: Yasuhito Suzuki, Tokyo (JP); Haruo Shimamoto, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/915,366

(22) Filed: Jul. 27, 2001

(30) Foreign Application Priority Data
Jan. 26, 2001 (JP) 2001-019241

(51) Int. Cl. H01L 23/02

(52) U.S. Cl. 257/678

(57) ABSTRACT

A semiconductor package has a die pad, a die mounted on the die pad, a plurality of outer leads electrically connected to electrodes of the die by bonding wires, and a sealing member. The sealing member seals therein the die, the bonding wires, parts of the outer leads and a part of the die pad. Further the sealing member has an upper surface on the side of the die and a lower surface on the side of the die pad. The outer leads have upper connecting surfaces on the side of the upper surface of the sealing member, and lower connecting surfaces on the side of the lower surface of the sealing member. The outer leads have a height from a plane including the lower surface of the sealing member greater than that of the upper surface of the sealing member from the same plane.

### BACKGROUND OF THE INVENTION

1. Field of the Invention

The present invention relates to a semiconductor package and a semiconductor device and, more particularly, to a semiconductor package generally called a very thin plastic QFN package (Quad Flat Nonlead package), and a semiconductor device.

2. Background Art

FIG. 9A shows a conventional semiconductor package 10, i.e., a QFN package, having outer leads 1 and a resin sealing 3. The resin sealing 3 has an upper surface 3a.

FIG. 9B is a typical sectional view in a plane parallel to an XZ plane or YZ plane in FIG. 9A. Shown in FIG. 9B are the outer leads 1, lower connecting surfaces 1b of the outer leads 1, a die pad 2, a die (silicon chip) 6 bonded to the die pad 2, the resin sealing 3, the upper surface 3a of the resin sealing 3, the lower surface 3b of the resin sealing 3, bonding wires 4 electrically connecting the die 6 to the outer leads 1, a bonding layer 5 of solder bonding the die 6 to the die pad 2, and the semiconductor package 10.

The semiconductor package 10 is put on a printed wiring board, not shown, with the lower surfaces 1b of the outer leads 1 of the semiconductor package 10 facing the surface of the printed wiring board, and the outer leads 1 are soldered to electrodes formed on the printed wiring board.

Technique disclosed in Japanese Patent Laid-Open No. 1993-183103 forms a recess in the back surface of a printed wiring board mounted with a memory chip and stacks printed wiring boards to achieve a high packaging density.

As mentioned above, in the conventional semiconductor package, the connecting surfaces of the outer leads are formed only on the side of the lower surfaces of the package. Therefore, additional, special members are necessary to stack up the semiconductor packages, which is an obstacle to the formation of semiconductor device in a high packaging density.

Since the connecting surfaces of the outer leads are formed only on the side of the lower surface of the package, the semiconductor package can be mounted on a printed wiring board only in a limited direction; that is, the semiconductor package can be mounted on a printed wiring board only with the lower surface of the semiconductor package facing the printed wiring board.

Therefore, the die pad exposed in the lower surface of the semiconductor package is always in contact with or close to the printed wiring board. Generally, the die pad is formed of a metal having a high thermal conductivity, such as copper, and most part of heat generated by the die is transferred to the die pad. Since the dissipation of heat from the die pad is obstructed by the printed wiring board in contact with or lying close to the die pad, heat is apt to be accumulated in the die and the die pad. Heat that is not dissipated but accumulated in the die and the die pad is unignorable when the semiconductor device is used in some working environment. The accumulated heat will heat the die at a high temperature in the course of time and will cause the semiconductor device to malfunction.

### SUMMARY OF THE INVENTION

The present invention has been made to solve the aforesaid problems and it is therefore an object of the present invention to provide a semiconductor package capable of being stacked on a printed wiring board in comparatively simple construction, having a die pad in the lower surface thereof, and capable of efficiently dissipating heat accumulated in the die pad and of achieving a high packaging density with high reliability.

According to one aspect of the present invention, a semiconductor package comprises a die pad, a die mounted on the die pad, a plurality of outer leads electrically connected to electrodes of the die by bonding wires, respectively, and a sealing member. The sealing member seals therein the die, the bonding wires, parts of the outer leads and a part of the die pad. Further the sealing member has an upper surface on the side of the die and a lower surface on the side of the die pad. The outer leads have upper electrical connecting surfaces on the side of the upper surface of the sealing member, and lower electrical connecting surfaces on the side of the lower surface of the sealing member, respectively. Further the outer leads have a height from a plane including the lower surface of the sealing member greater than that of the upper surface of the sealing member from the same plane.

According to another aspect of the present invention, a semiconductor device comprises a printed wiring board and a plurality of semiconductor packages. The plurality of semiconductor packages is stacked up on the printed wiring board with outer leads included therein. Further each of the plurality of semiconductor packages comprises, a die pad, a die mounted on the die pad, the outer leads electrically connected to electrodes of the die by bonding wires, respectively, and a sealing member. The sealing member seals therein the die, the bonding wires, parts of the outer leads and a part of the die pad. Further the sealing member has an upper surface on the side of the die and a lower surface on the side of the die pad. The outer leads have upper electrical connecting surfaces on the side of the upper surface of the sealing member, and lower electrical connecting surfaces on the side of the lower surface of the sealing member, respectively. Further the outer leads have a height from a plane including the lower surface of the sealing member greater than that of the upper surface of the sealing member from the same plane.

According to another aspect of the present invention, a semiconductor device comprises a printed wiring board and a semiconductor package. The semiconductor package is mounted on the printed wiring board with a upper surface of a sealing member thereof facing the printed wiring board and outer leads thereof connected to electrodes formed on the printed wiring board. Each of the plurality of semiconductor packages comprises a die pad, a die mounted on the die pad, the outer leads electrically connected to electrodes of the die by bonding wires, respectively, and the sealing member. The sealing member seals therein the die, the bonding wires, parts of the outer leads and a part of the die pad. Further the sealing member has the upper surface on the side of the die and a lower surface on the side of the die pad. The outer leads have upper electrical connecting surfaces on the side of the upper surface of the sealing member, and lower electrical connecting surfaces on the side of the lower surface of the sealing member, respectively. Further the outer leads have a height from a plane including the lower surface of the sealing member greater than that of the upper surface of the sealing member from the same plane.

Other and further objects, features and advantages of the invention will appear more fully from the following description.

### BRIEF DESCRIPTION OF THE DRAWINGS

FIG. 1 is a typical perspective view of a semiconductor package in a first embodiment according to the present invention;

FIG. 2 is a typical sectional view taken on an XZ plane or a YZ plane in FIG. 1;

FIG. 3 is a typical perspective view of a semiconductor device in a second embodiment according to the present invention;

FIG. 4 is a typical sectional view taken on an XZ plane or a YZ plane in FIG. 3;

FIG. 5 is a typical sectional view of a semiconductor device in a third embodiment according to the present invention;

FIG. 6 is a typical sectional view of a semiconductor device in a fourth embodiment according to the present invention;

FIG. 7 is a typical sectional view of a semiconductor device in a fifth embodiment according to the present invention;

FIG. 8 is a typical sectional view of a semiconductor device in a sixth embodiment according to the present invention;

FIG. 9A is a typical perspective view of a conventional semiconductor package; and

FIG. 9B is a typical sectional view taken on an XZ plane or a YZ plane in FIG. 9A.

### DETAILED DESCRIPTION OF THE PREFERRED EMBODIMENTS

First Embodiment

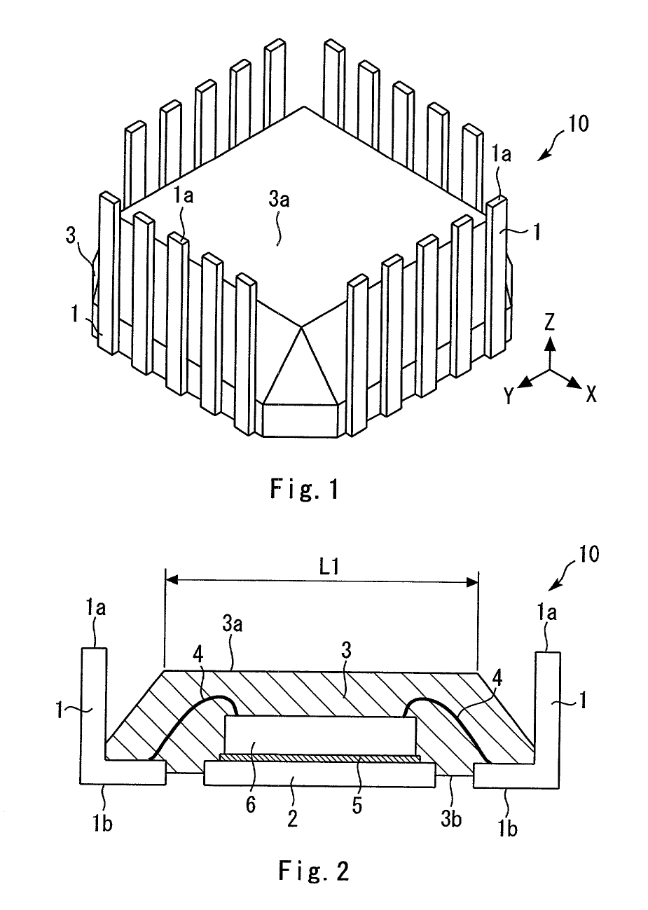

The first embodiment of the present invention will be hereinafter described with reference to the attached drawing. Referring to FIG. 1 showing a semiconductor package 10 in a first embodiment according to the present invention, there are shown outer leads 1, the upper connecting surfaces 1a of the outer leads 1, a sealing member 3 and the upper surface 3a of the sealing member 3. The semiconductor package 10 is the so-called QFN package provided with the plurality of outer leads 1 on its four sides.

FIG. 2 is a typical sectional view taken on an XZ plane or a YZ plane in FIG. 1. Shown in FIG. 2 are the outer leads 1, the upper connecting surfaces 1a of the outer leads 1, the lower connecting surfaces 1b of the outer leads 1, a die pad 2, a die 6 mounted on the die pad 2, the sealing member 3, the upper surface 3a of the sealing member 3 on the side of the die 6, the lower surface 3b of the sealing member 3 formed on the side of the die pad 2, bonding wires 4 electrically connecting the outer leads 1 to the electrodes of the die 6, a bonding layer 5 and the semiconductor package 10. A projection region of the upper surface 3a of the sealing member 3 is indicated at L1.

The outer leads 1 have connecting surfaces in the same direction of both the sides of the upper and the lower surface of the sealing member 3; that is, the outer leads 1 have the upper connecting surfaces 1a in the same direction of the side of the upper surface 3a of the sealing member 3, and the lower connecting surfaces 1b in the same direction of the side of the lower surface 3b of the sealing member 3.

The upper connecting surfaces 1a and the lower connecting surfaces 1b of the outer leads 1 can be bonded with a bonding material, such as solder, to the connecting surfaces of electrodes formed on a printed wiring board or the connecting surfaces of the outer leads of another semiconductor package to connect the semiconductor package electrically to the printed wiring board or another semiconductor package.

The outer leads 1 are formed in a height greater than that of the upper surface 3a of the sealing member 3. Thus, the upper connecting surfaces 1a of the outer leads 1 are on a level with respect to the Z-axis higher than that of the upper surface 3a of the sealing member 3. The outer leads 1 have a shape resembling the letter L (a L-shape) seen from a cross section in parallel with the XZ plane and the YZ plane. The upper connecting surfaces 1a of the outer leads 1 are arranged outside the projection region L1 of the upper surface 3a of the sealing member 3.

The sealing member 3 is formed of a material bondable to the die pad 2 and the outer leads 1, such as a resin. The sealing member 3 protects the die 6 from external forces.

The sealing member 3 is formed, for example, by the following process. The die 6 is bonded to the die pad 2 and the electrodes of the die 6 are connected to the outer leads 1 by the bonding wires 4, respectively, on a frame, not shown. The die 6 bonded to the die pad 2 and the outer leads 1 connected to the die 6 are placed in a mold and the resin is injected into the mold. The mold is heated to cure the resin injected into the mold to complete the sealing member 3. The outer leads 1 are cut and are bent in the L-shape to complete the semiconductor package 10 of a desired shape.

Either the upper connecting surfaces 1a of the outer leads 1 or the lower connecting surfaces 1b of the outer leads 1 can be selectively used or both the upper connecting surfaces 1a and the lower connecting surfaces 1b of the outer leads 1 can be used. Thus, the semiconductor package 10 can be set on a printed wiring board in either a normal position with the upper surface 3a of the sealing member 3 facing up or an inverted position with the upper surface 3a of the sealing member 3 facing down. A plurality of semiconductor packages similar to the semiconductor package 10 can be stacked up.

Mounting of the semiconductor package 10 in the first embodiment on a printed wiring board will be described later in connection with the description of other embodiments.

The semiconductor package 10 in the first embodiment has comparatively simple construction, is capable of being mounted on a printed wiring board in either a normal position or an inverted position and semiconductor packages similar to the semiconductor package 10 can be stacked up. Thus the semiconductor package 10 in the first embodiment increases the degree of freedom of arrangement, and semiconductor packages similar to the semiconductor package 10 in the first embodiment can be mounted on a small printed wiring board in a high packaging density. When the semiconductor package 10 is mounted on a printed wiring board with the upper connecting surfaces 1a of the outer leads 1 thereof facing the surface of the printed wiring board, the die pad 2 is not in direct contact with the printed wiring board and hence heat transferred to the die pad 2 can be readily dissipated.

When fabricating the semiconductor package 10 in the first embodiment, the outer leads 1 are bent in the L-shape after forming the sealing member 3. The outer leads 1 are not necessarily to be formed in the L-shape; the same may be formed in a shape other than the L-shape, such as a turned square U-shape. The outer leads 1 may be shaped so that the upper connecting surfaces 1a thereof lie in the projection region L1.

Second Embodiment

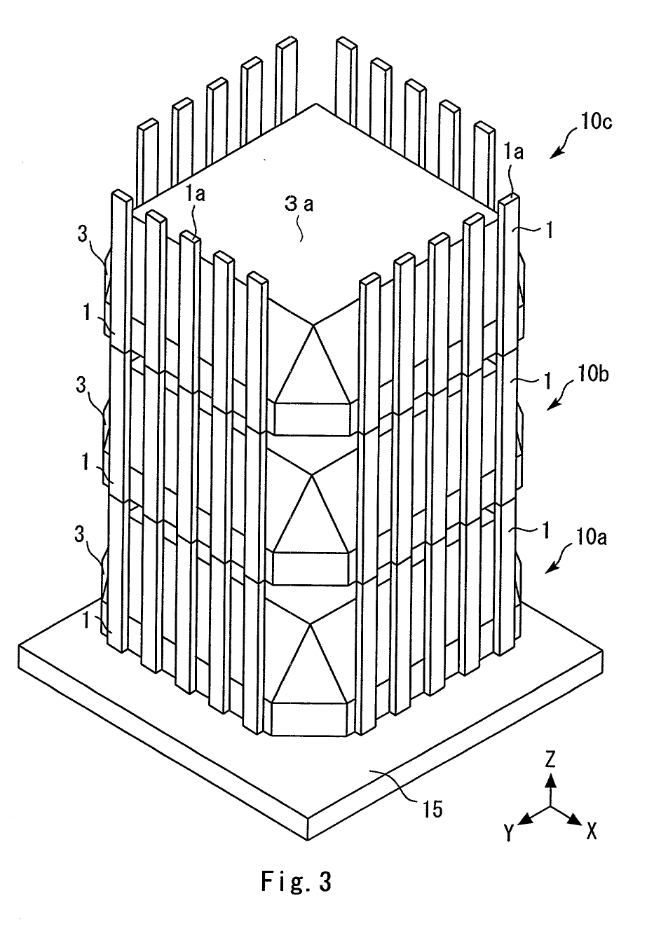

The second embodiment of the present invention will be hereinafter described with reference to the attached drawing. FIG. 3 is a typical perspective view of a semiconductor device in a second embodiment according to the present invention. Shown in FIG. 3 are outer leads 1, the upper connecting surfaces 1a of the outer leads 1, sealing members 3, the upper surfaces 3a of the sealing members 3, semiconductor packages 10a, 10b and 10c, and printed wiring board 15. The semiconductor packages 10a, 10b and 10c are similar to the semiconductor package 10 in the first embodiment provided with the L-shaped outer leads 1. The semiconductor package 10a is mounted on the printed wiring board 15, the semiconductor package 10b is mounted on the semiconductor package 10a, and the semiconductor package 10c is mounted on the semiconductor package 10b.

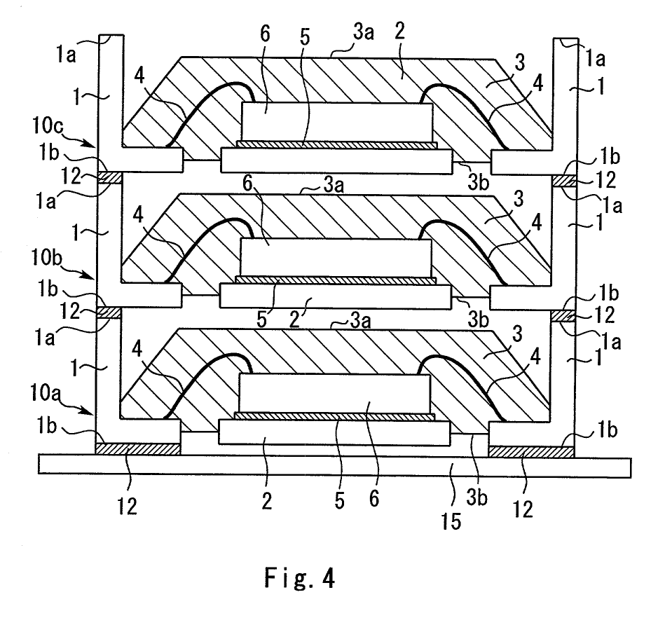

FIG. 4 is a typical sectional view taken on an XZ plane or a YZ plane in FIG. 3. Shown in FIG. 4 are the outer leads 1, the upper connecting surfaces 1a of the outer leads 1, the lower connecting surfaces 1b of the outer leads 1, die pads 2, the sealing members 3, the upper surfaces 3a of the sealing members 3, the lower surfaces 3b of the sealing members 3, bonding wires 4, bonding layers 5, dies 6, the semiconductor packages 10a, 10b and 10c, a bonding material 12 and the printed wiring board 15.

When mounting the first semiconductor package 10a on the printed wiring board 15, the lower connecting surfaces 1b of the outer leads 1 are bonded to predetermined electrodes formed on the printed wiring board 15 by the bonding material 12. When mounting the second semiconductor package 10b on the first semiconductor package 10a, the lower connecting surfaces 1b of the outer leads 1 of the second semiconductor package 10b are bonded to the upper connecting surfaces 1a of the outer leads 1 of the first semiconductor package 10a by the bonding material 12. Similarly, when mounting the third semiconductor package 10c on the second semiconductor package 10b, the lower connecting surfaces 1b of the outer leads 1 of the third semiconductor package 10c are bonded to the upper connecting surfaces 1a of the outer leads 1 of the second semiconductor package 10b by the bonding material 12.

The outer leads 1 have rigidity large enough to withstand the deforming action of forces exerted thereon when the semiconductor packages 10a, 10b and 10c are stacked up. Since all the four sides of each of the second semiconductor package 10b and the third semiconductor package 10c are supported, the semiconductor packages 10a, 10b and 10c are stacked stably. Since with the above-mentioned construction the gaps between the stacked semiconductor packages 10a, 10b and 10c are opened in four directions, heat transferred to the die pads 2 can be readily dissipated.

As apparent from the foregoing description, the semiconductor packages 10a, 10b and 10c of the semiconductor device in the second embodiment have comparatively simple construction and are capable of being stacked up on the printed wiring board 15. Thus the semiconductor packages 10a, 10b and 10c of the semiconductor device in the second embodiment can be mounted on the printed wiring board 15 in a small size with a high packaging density. Since the die pads 2 are able to dissipate heat efficiently, the reliability of the semiconductor packages 10a, 10b and 10c is improved.

Although all the semiconductor packages 10a, 10b and 10c are stacked up on the printed wiring board 15 in a normal position with the upper surfaces 3a of the sealing members 3 thereof facing up in the second embodiment, the semiconductor packages 10a, 10b and 10c may be stacked up in desired positions, respectively. When the semiconductor packages 10a, 10b and 10c are stacked up in an inverted position with the lower surfaces 3b of the sealing member 3 thereof facing up, heat transferred to the die pads 2 of all the semiconductor packages 10a, 10b and 10c can be readily dissipated.

Third Embodiment

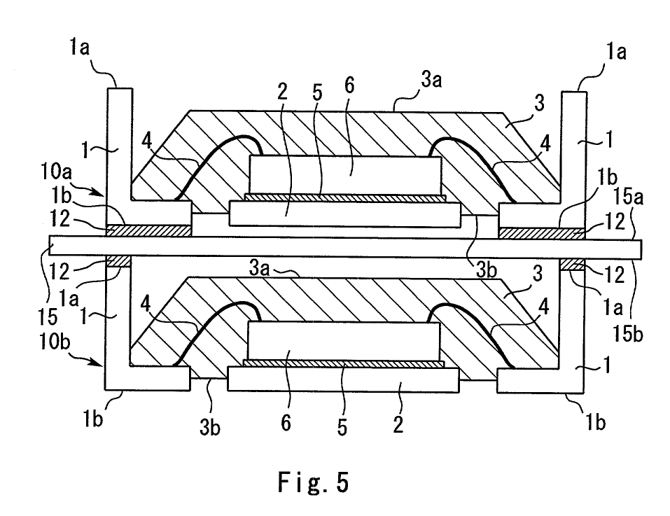

The third embodiment of the present invention will be hereinafter described with reference to the attached drawing. FIG. 5 is a typical sectional view of a semiconductor device in a third embodiment according to the present invention. As shown in FIG. 5, the semiconductor device in the third embodiment is similar to that in the second embodiment, except that the semiconductor device is built by connecting semiconductor packages 10a and 10b to the opposite surfaces of a printed wiring board 15, respectively.

Referring to FIG. 5, the lower connecting surfaces 1b of the outer leads 1 of the upper semiconductor package 10a are bonded to electrodes formed on the upper surface 15a of the printed wiring board 15 by a bonding material 12, and the upper connecting surfaces 1a of the outer leads 1 of the lower semiconductor package 10b are bonded to electrodes formed on the lower surface 15b of the printed wiring board 15 by a bonding material 12.

Electric circuits respectively for the semiconductor packages 10a and 10b are formed on the upper surface 15a and the lower surface 15b of the printed wiring board 15, respectively.

As apparent from the foregoing description, the semiconductor packages 10a and 10b of the semiconductor device in the third embodiment have comparatively simple construction and are capable of being connected to the opposite surfaces 15a and 15b of the printed wiring board 15. Thus the semiconductor device can be formed in a small size with a high density.

Fourth Embodiment

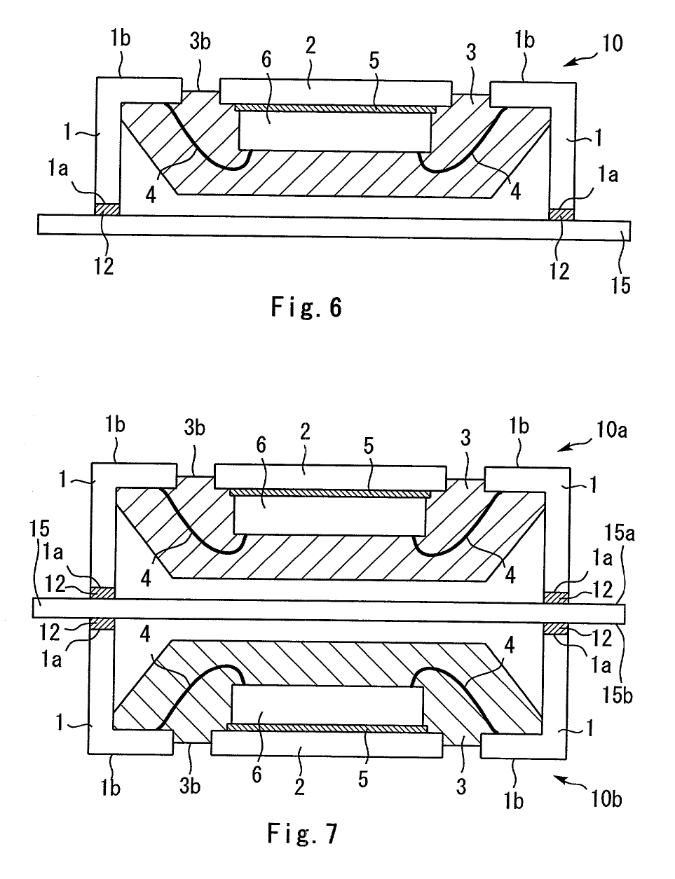

The fourth embodiment of the present invention will be hereinafter described with reference to the attached drawing. FIG. 6 is a typical sectional view of a semiconductor device in a fourth embodiment according to the present invention. The semiconductor device in the fourth embodiment is formed by mounting a semiconductor package 10 similar to the semiconductor package 10 in the first embodiment on a surface of a printed wiring board 15.

The semiconductor package 10 is mounted on the printed wiring board 15 by facing the upper connecting surface 1a of the outer leads 1 to the printed wiring board 15. That is, in FIG. 6, the upper connecting surfaces 1a of the outer leads 1 of the upper semiconductor package 10 are bonded to electrodes formed on the upper surface of the printed wiring board 15 by a bonding material 12.

As described above, in the construction of the semiconductor device of the fourth embodiment according to the present invention, the semiconductor packages 10 is mounted on the printed wiring board 15 with the die pad 2 facing away from the printed wiring board 15, and thereby the die pad 2 is exposed always to the atmosphere. Thus heat transferred to the die pad 2 can be efficiently dissipated, the semiconductor device can be formed in a high packaging density and the semiconductor device has high reliability.

Fifth Embodiment

The fifth embodiment of the present invention will be hereinafter described with reference to the attached drawing. FIG. 7 is a typical sectional view of a semiconductor device in a fifth embodiment according to the present invention. The semiconductor device in the fifth embodiment is formed by connecting semiconductor packages 10a and 10b similar to the semiconductor package 10 in the first embodiment on the opposite surfaces of a printed wiring board 15, respectively, in a manner similar to that in which the semiconductor package 10 of the semiconductor device in the fourth embodiment is connected to the printed wiring board 15.

As shown in FIG. 7, the upper surfaces 1a of the outer leads 1 of the upper semiconductor package 10a are bonded to predetermined electrodes formed on the upper surface 15a of the printed wiring board 15 by a bonding material 12, and the upper surfaces 1a of the outer leads 1 of the lower semiconductor package 10b are bonded to predetermined electrodes formed on the lower surface 15b of the printed wiring board 15 by a bonding material 12.

Since the semiconductor packages 10a and 10b are connected to the upper and the lower surface of the printed wiring board 15, respectively, with their die pads 2 facing away from the printed wiring board 15, the die pads 2 are exposed always to the atmosphere. Thus heat transferred to the die pads 2 can be efficiently dissipated, the semiconductor device can be formed in a high packaging density and the semiconductor device has high reliability.

Sixth Embodiment

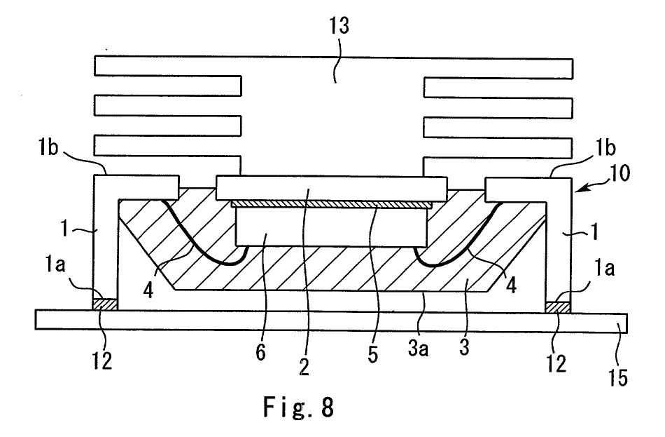

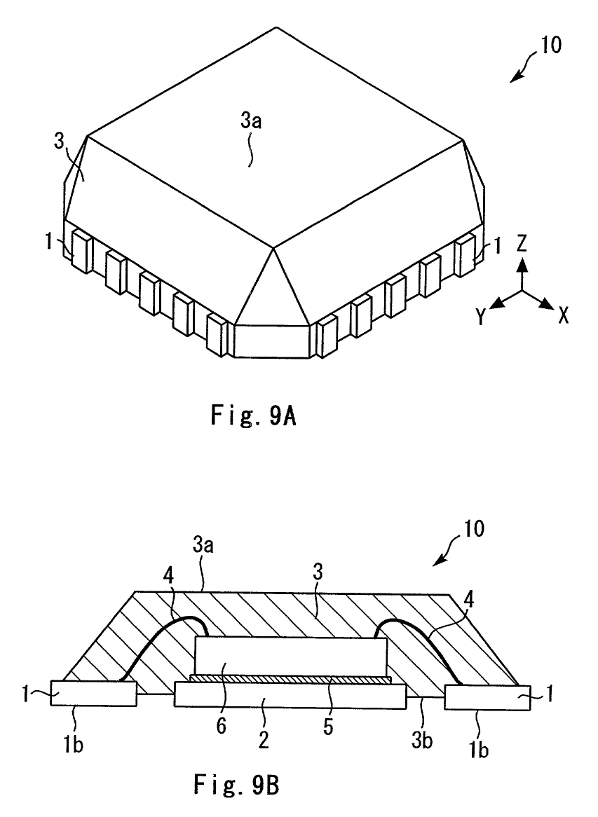

The sixth embodiment of the present invention will be hereinafter described with reference to the attached drawing. FIG. 8 is a typical sectional view of a semiconductor device in a sixth embodiment according to the present invention. The semiconductor device in the sixth embodiment is similar to that in the fourth embodiment, except that the former employs a semiconductor package 10 having a die pad 2 provided with a cooling fin 13.

The cooling fin 13 is formed of a material, such as aluminum alloy, having a relatively high thermal conductivity to transfer heat efficiently from the die pad 2 to the cooling fin 13. The cooling fin 13 is formed in a shape having a large surface area, such as the shape of superposed disks, to dissipate heat efficiently into the atmosphere. The semiconductor device in the sixth embodiment is capable of dissipating heat generated by a die 6 included in the semiconductor package 10 more efficiently than that in the fourth embodiment.

As apparent from the foregoing description, the cooling fin 13 enhances the heat dissipating ability of the die pad 2 and hence the semiconductor device has improved reliability.

The present invention is not limited in its practical application to the preferred embodiments thereof specifically described herein and many changes and variations may be made herein without departing from the scope thereof. The present invention is applicable to semiconductor packages other than the QFN packages. The numbers, positions and shapes of those component members of the preferred embodiments described herein are only examples and are subject to change. Like parts corresponding to those in each of the drawings are identified by the same reference numerals.

As apparent from the foregoing description, the semiconductor packages according to the present invention are simple in construction and are capable of being mounted on a printed wiring board in an optional position and can be stacked up in desired positions on a printed wiring board. Heat transferred to the exposed die pad of the semiconductor package can be efficiently dissipated and the semiconductor device can be formed in a small size and in a high packaging density and has high reliability.

In another aspect of the present invention, since the heat generated by the die can be efficiently dissipated into the atmosphere, the semiconductor package will not be heated at an excessively high temperature, the malfunction of the semiconductor device due to heat can be avoided, and the semiconductor device has high reliability.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-019241, filed on Jan. 26, 2001 including specification, claims, drawings and summary, on which the Convention priority of the present application is based, are incorporated herein by reference in its entirety.

What is claimed is:

1. A semiconductor package comprising:
a die pad;
a die mounted on the die pad;
a plurality of outer leads electrically connected to electrodes of the die by bonding wires, respectively; and
a sealing member sealing therein the die, the bonding wires, parts of the outer leads and a part of the die pad, and having an upper surface on the side of the die and a lower surface on the side of the die pad;
wherein the outer leads have upper electrical connecting surfaces on the side of the upper surface of the sealing member, and lower electrical connecting surfaces on the side of the lower surface of the sealing member, respectively, and the outer leads have a height from a plane including the lower surface of the sealing member greater than that of the upper surface of the sealing member from the same plane.

2. The semiconductor package according to claim 1, wherein the upper electrical connecting surfaces of the outer leads formed on the side of the upper surface of the sealing member lie outside a projection region of the upper surface of the sealing member.

3. The semiconductor package according to claim 1, wherein the sealing member has four sides, and the outer leads are formed on the four sides of the sealing member.

4. The semiconductor package according to claims 1, wherein the outer leads are formed in an L-shape.

5. A semiconductor device comprising:
a printed wiring board; and
a plurality of semiconductor packages, stacked up on the printed wiring board with outer leads included therein; wherein each of the plurality of semiconductor packages comprises,
a die pad;
a die mounted on the die pad;
the outer leads electrically connected to electrodes of the die by bonding wires, respectively; and
a sealing member sealing therein the die, the bonding wires, parts of the outer leads and a part of the die pad, and having an upper surface on the side of the die and a lower surface on the side of the die pad;
wherein the outer leads have upper electrical connecting surfaces on the side of the upper surface of the sealing member, and lower electrical connecting surfaces on the side of the lower surface of the sealing member, respectively, and the outer leads have a height from a plane including the lower surface of the sealing member greater than that of the upper surface of the sealing member from the same plane.

6. The semiconductor device according to claim 5, wherein the upper electrical connecting surfaces of the outer leads formed on the side of the upper surface of the sealing member lie outside a projection region of the upper surface of the sealing member.

7. The semiconductor device according to claim 5, wherein the sealing member has four sides, and the outer leads are formed on the four sides of the sealing member.

8. The semiconductor device according to claims 5, wherein the outer leads are formed in an L-shape.

9. A semiconductor device comprising:
a printed wiring board; and
a semiconductor package, mounted on the printed wiring board with a upper surface of a sealing member thereof facing the printed wiring board and outer leads thereof connected to electrodes formed on the printed wiring board; wherein each of the plurality of semiconductor packages comprises,
a die pad;
a die mounted on the die pad;
the outer leads electrically connected to electrodes of the die by bonding wires, respectively; and
the sealing member sealing therein the die, the bonding wires, parts of the outer leads and a part of the die pad, and having the upper surface on the side of the die and a lower surface on the side of the die pad;
wherein the outer leads have upper electrical connecting surfaces on the side of the upper surface of the sealing member, and lower electrical connecting surfaces on the side of the lower surface of the sealing member, respectively, and the outer leads have a height from a plane including the lower surface of the sealing member greater than that of the upper surface of the sealing member from the same plane.

10. The semiconductor device according to claim 9, wherein the upper electrical connecting surfaces of the outer leads formed on the side of the upper surface of the sealing member lie outside a projection region of the upper surface of the sealing member.

11. The semiconductor device according to claim 9, wherein the sealing member has four sides, and the outer leads are formed on the four sides of the sealing member.

12. The semiconductor device according to claims 9, wherein the outer leads are formed in an L-shape.

13. The semiconductor device according to claim 9, wherein the die pad of the semiconductor package is provided on its exposed surface with a cooling fin.
